(19) United States
(12) Patent Application Publication
(10) Pub. No.: US 2012/0049255 A1
(43) Pub. Date: Mar. 1, 2012

(54) GATE STRUCTURE HAVING A BURIED GATE ELECTRODE, SEMICONDUCTOR DEVICE INCLUDING THE SAME

(76) Inventor: Ho-In RYU, Suwon-si (KR)

(21) Appl. No.: 13/168,200

(22) Filed: Jun. 24, 2011

(30) Foreign Application Priority Data
Aug. 25, 2010 (KR) 10-2010-0082245

(51) Int. Cl. H01L 27/06; H01L 29/78

(52) U.S. Cl. 257/296; 257/330; 257/E29.262; 257/E27.014

(57) ABSTRACT

A gate structure includes a gate insulation layer, a gate electrode and a capping layer pattern. The gate insulation layer is formed on an inner wall of a recess in a substrate. The gate electrode is formed on the gate insulation layer to partially fill the recess. The capping layer pattern is formed of silicon oxide on the gate electrode and the gate insulation layer to fill a remaining portion of the recess.

### CROSS-REFERENCE TO RELATED APPLICATION

This application claims priority under 35 USC §119 to Korean Patent Application No. 10-2010-0082245, filed on Aug. 25, 2010, the disclosure of which is hereby incorporated by reference herein in its entirety.

### BACKGROUND

1. Technical Field

Example embodiments relate to a gate structure, a semiconductor device including the same, a method of forming the gate structure and a method of manufacturing a semiconductor device using the same. More particularly, example embodiments relate to a gate structure having a buried gate electrode, a semiconductor device including the same, a method of forming the gate structure and a method of manufacturing a semiconductor device using the same.

2. Description of the Related Art

As the integration degree and the speed of semiconductor integrated circuits continue to increase, the pattern size of the semiconductor integrated circuits may be required to decrease. Accordingly, to increase a channel length, a transistor having a buried gate electrode may be used.

When the buried gate electrode is used, a capping layer including a silicon nitride may be formed on a top surface of the buried gate electrode. However, different physical characteristics between the capping layer and a gate insulation layer adjacent to the buried gate electrode may cause a stress, and thus the gate insulation layer may be deteriorated.

Accordingly, there is a need in the art for a gate structure which may prevent the stress and the resulting deterioration of the gate insulation layer which occurs in conventional gate structures and for methods of forming the same.

### SUMMARY

Example embodiments provide a buried gate structure having good characteristics.

Example embodiments provide a semiconductor device including the buried gate structure.

Example embodiments provide a method of forming the buried gate structure having good characteristics.

Example embodiments provide a method of manufacturing the semiconductor device using the method of forming the buried gate structure.

According to example embodiments, there is provided a gate structure. The gate structure comprises a gate insulation layer, a gate electrode and a capping layer pattern. The gate insulation layer is formed on an inner wall of a recess in a substrate. The gate electrode is formed on the gate insulation layer and partially fills the recess. The capping layer pattern is formed on the gate electrode and the gate insulation layer. The capping layer pattern fills a remaining portion of the recess and includes silicon oxide.

In example embodiments, the gate insulation layer may include silicon oxide.

In example embodiments, the capping layer pattern may protrude from a top surface of the substrate.

According to example embodiments, there is provided a semiconductor device. The semiconductor device comprises a first transistor, a blocking layer pattern, a bit line, a capacitor, and a second transistor. The first transistor includes a first gate structure, a first impurity region, and a second impurity region. The first gate structure includes a first gate insulation layer, a first gate electrode, and a capping layer pattern. The first gate insulation layer is formed on an inner wall of a recess in a substrate in a first region. The substrate is divided into the first region and a second region. The first gate electrode is formed on the first gate insulation layer and partially fills the recess. The capping layer pattern is formed on the first gate electrode and the first gate insulation layer. The capping layer pattern fills a remaining portion of the recess and includes silicon oxide. The first impurity region and the second impurity region are formed at upper portions of the substrate in the first region adjacent to the first gate structure. The blocking layer pattern is formed on the substrate in the first region. The blocking layer pattern covers the first transistor. The bit line is formed on the blocking layer pattern and is electrically connected to the first impurity region. The capacitor is electrically connected to the second impurity region. The second transistor is formed on the substrate in the second region.

In example embodiments, the gate insulation layer may include silicon oxide.

In example embodiments, the blocking layer may include silicon nitride.

In example embodiments, the capping layer pattern may protrude from a top surface of the substrate.

In example embodiments, the semiconductor device may further comprise a silicon oxide layer formed on the blocking layer pattern.

In example embodiments, the second transistor may include a second gate structure and a third impurity region. The second gate structure may include a second gate insulation layer and a second gate electrode sequentially stacked on the substrate in the second region. The third impurity region may be formed at an upper portion of a substrate adjacent to the second gate structure in a second region. The second gate insulation layer pattern may include a material substantially the same as a material of the silicon oxide layer.

In example embodiments, the semiconductor device may further comprise a plug through the blocking layer pattern and the mask. The plug may contact the bit line and the first impurity region.

According to example embodiments, there is provided a method of forming a gate structure. In the methods, a gate insulation layer is formed on an inner wall of a recess in a substrate. A gate electrode is formed on the gate insulation layer and partially fills the recess. A capping layer pattern is formed on the gate electrode and the gate insulation layer. The capping layer pattern fills a remaining portion of the recess and includes silicon oxide.

In example embodiments, prior to forming the gate insulation layer, a mask and a polish stop layer pattern may be further formed on the substrate sequentially, and an upper portion of the substrate may be further removed using the mask and the polish stop layer pattern as etching masks to form the recess. The recess and side-walls of the mask and the polish stop layer pattern may define a trench.

In example embodiments, when the capping layer pattern is formed, a capping layer may be formed on the gate electrode, the gate insulation layer, the mask and the polish stop layer pattern, and an upper portion of the capping layer may be planarized using the polish stop layer pattern as a polishing endpoint. The capping layer may fill a remaining portion of the trench

According to example embodiments, there is provided a method of manufacturing a semiconductor device. In the methods, a first gate insulation layer is formed on an inner wall of a recess in a substrate in a first region of the substrate. A first gate electrode is formed on the first gate insulation layer and partially fills the recess. A capping layer pattern is formed on the first gate electrode and the first gate insulation layer to form a first gate structure. The capping layer pattern fills a remaining portion of the recess and includes silicon oxide. A blocking layer pattern is formed on the substrate in the first region and covers a top surface of the first gate structure. A bit line is formed on the blocking layer pattern.

In example embodiments, the substrate may be divided into the first region and a second region. When the blocking layer pattern is formed, a blocking layer may be formed on the substrate in the first and the second regions, a photoresist pattern may be formed on the blocking layer, and the blocking layer may be etched by a dry etching process using the photoresist pattern as an etching mask to thereby form a blocking layer pattern located only in the first region. The blocking layer may cover the top surface of the first gate structure. The photoresist pattern may cover the first region.

In example embodiments, prior to forming the first gate insulation layer, a first impurity region and a second impurity region may be further formed at upper portions of the substrate in the first region. The bit line is formed to be electrically connected to the first impurity region.

In example embodiments, a capacitor electrically connected to the second impurity region may be further formed.

In example embodiments, a second gate structure may be further formed and a third impurity region may be further formed at an upper portion of the substrate in a second region. The second gate structure may include a second gate insulation layer and a second gate electrode sequentially stacked on the substrate adjacent to the second gate structure in the second region.

According to example embodiments, a method of manufacturing a semiconductor device is provided. The method includes forming impurity regions in a first region of a substrate divided into the first region and a second region, etching an upper portion of the substrate to form a trench recessed within the substrate and the trench divides the impurity regions into a first impurity region and a second impurity region in the first region of the substrate, forming a first gate insulation layer on an inner wall of the trench in the substrate in the first region and the first gate insulation layer is formed of an oxide, forming a first gate electrode layer on the first gate insulation layer to fill the trench, removing an upper portion of the first gate electrode layer to form a first gate electrode partially filling the trench, and forming a capping layer pattern on the first gate electrode and the first gate insulation layer to form a first gate structure. The capping layer pattern fills a remaining portion of the trench and includes an oxide substantially the same as or similar to the oxide of the first gate insulation layer. The method further includes forming a blocking layer pattern on the substrate only in the first region, with the blocking layer pattern covering a top surface of the first gate structure and including silicon nitride, forming a first plug in the blocking layer pattern, forming a bit line on the blocking layer pattern and the bit line is electrically connected to the first plug, forming a second gate structure including a second gate insulation layer pattern and a second gate electrode sequentially stacked on the substrate in the second region, forming a spacer on a sidewall of the second gate structure, forming a third impurity region at an upper portion of the substrate adjacent to the second gate structure in the second region by an ion implantation process using the second gate structure and the spacer as ion implantation masks, forming a first interlayer covering the bit line, the second gate structure and the spacer, forming a second plug in the first interlayer and the second plug is electrically connected to the second impurity region, forming a polish stop layer on the second plug and the first insulating interlayer and forming a lower electrode in the polish stop layer and on the first insulating interlayer.

According to example embodiments, a capping layer pattern including an oxide may be formed on a buried gate electrode, and thus a gate insulation layer including an oxide may not have a stress during a process for forming the capping layer pattern and a process thereafter. Accordingly, the gate insulation layer may have desired characteristics. Additionally, a blocking layer including a nitride may be formed on the substrate in a first region, and thus the substrate may be protected from a plasma damage during subsequent processes for forming a bit line. and the blocking layer in a second region, in which peripheral circuits may be formed, may be removed by a dry etching process using the photoresist pattern to prevent the lifting of the photoresist pattern.

### BRIEF DESCRIPTION OF THE DRAWINGS

Example embodiments will be more clearly understood from the following detailed description taken in conjunction with the accompanying drawings. FIGS. 1 to 13 represent non-limiting, example embodiments as described herein.

FIGS. 1 to 10 are cross-sectional views illustrating a method of manufacturing a semiconductor device having a buried gate structure in accordance with an example embodiment;

FIG. 11 is a block diagram illustrating a memory card having the buried gate structure in accordance with an example embodiment;

FIG. 12 is a block diagram illustrating a portable device having the buried gate structure in accordance with an example embodiment; and

FIG. 13 is a block diagram illustrating a computer system having the buried gate structure in accordance with an example embodiment.

### DETAILED DESCRIPTION OF EXAMPLE EMBODIMENTS OF THE INVENTION

Various example embodiments will be described more fully hereinafter with reference to the accompanying drawings, in which some example embodiments are shown. The present inventive concept may, however, be embodied in many different forms and should not be construed as limited to the example embodiments set forth herein. In the drawings, the sizes and relative sizes of layers and regions may be exaggerated for clarity.

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Like numerals refer to like elements throughout.

Hereinafter, example embodiments will be explained in detail with reference to the accompanying drawings.

FIGS. 1 to 10 are cross-sectional views illustrating a method of manufacturing a semiconductor device having a buried gate structure in accordance with an example embodiment.

Referring to FIG. 1, impurity regions 103 and 105 may be formed at upper portions of a substrate 100 in a first region I by, for example, implanting impurities into the substrate 100, and an isolation layer 110 may be formed on the substrate 100 to define an active region and an inactive region in the substrate 100.

The substrate 100 may include a semiconductor substrate such as, for example, a silicon substrate or a germanium substrate, a substrate having a semiconductor layer and an insulation layer such as a silicon-on-insulator (SOI) substrate or a germanium-on-insulator (GOI) substrate, or a single crystalline metal oxide substrate. The substrate 100 may be divided into the first region I in which memory cells may be formed and a second region II in which peripheral circuits may be formed.

For example, in example embodiments, the impurities may include n-type impurities such as arsenic or phosphorus, and the impurity regions 103 and 105 may serve as source/drain regions of the memory cells.

The isolation layer 110 may be formed by, for example, a shallow trench isolation (STI) process. For example, after forming a first trench (not shown) at an upper portion of the substrate 100, an insulation layer filling the first trench may be formed on the substrate 100, and an upper portion of the insulation layer may be planarized to form the isolation layer 110. The isolation layer 110 may be formed by, for example, a chemical vapor deposition (CVD) process or a high density plasma chemical vapor deposition (HDP-CVD) process, etc. In an example embodiment, prior to forming the isolation layer 110, a liner (not shown) may be further formed on an inner wall of the first trench using, for example, a nitride.

An upper portion of the substrate 100 may be partially removed to form a second trench 140.

In example embodiments, after forming a mask layer and a polish stop layer on the substrate 100, the mask layer and the polish stop layer may be patterned by, for example, a photolithography process to form a polish stop layer pattern 130 and a mask 120, respectively. An upper portion of the substrate 100 may be etched using the polish stop layer pattern 130 and the mask 120 as etching masks to form the second trench 140. The second trench 140 may be defined as a space formed by a top surface of a recessed region of the substrate 100 and sidewalls of the mask 120 and the polish stop layer pattern 130.

For example, the mask layer may be formed using silicon oxide and the polish stop layer may be formed using silicon nitride.

As the second trench 140 is formed, impurity regions 103 and 105 may be divided into a first impurity region 103 and a second impurity region 105.

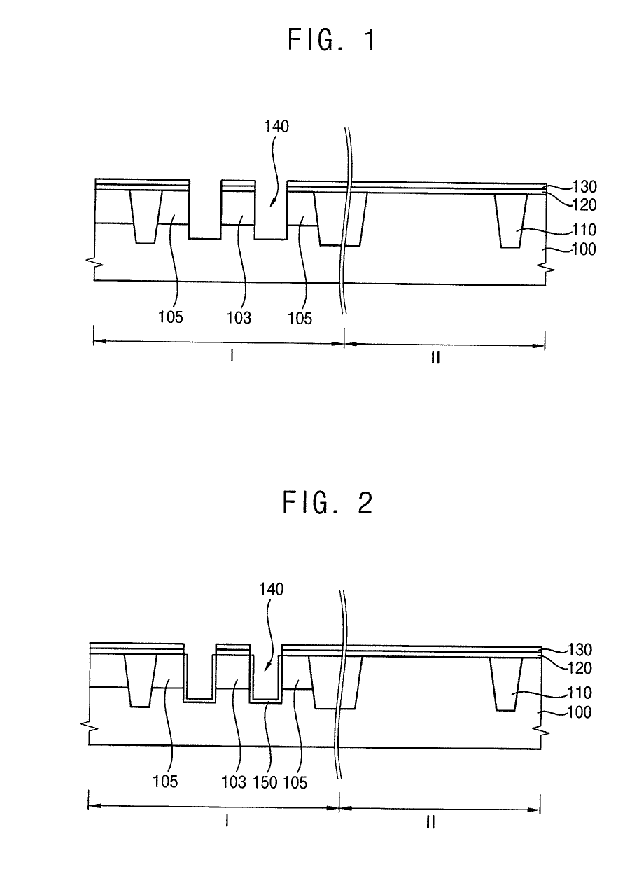

Referring to FIG. 2, a first gate insulation layer 150 may be formed on a top surface of the recessed region of the substrate 100.

In example embodiments, the first gate insulation layer 150 may be formed on the top surface of recessed region of the substrate 100 by, for example, a thermal oxidation process. In other example embodiments, the first gate insulation layer 150 may be formed by depositing, for example, a silicon oxide (SiO₂) or a metal oxide on the top surface of the recessed region of the substrate 100 by a CVD process. The metal oxide may include, for example, hafnium oxide, tantalum oxide, zirconium oxide, etc.

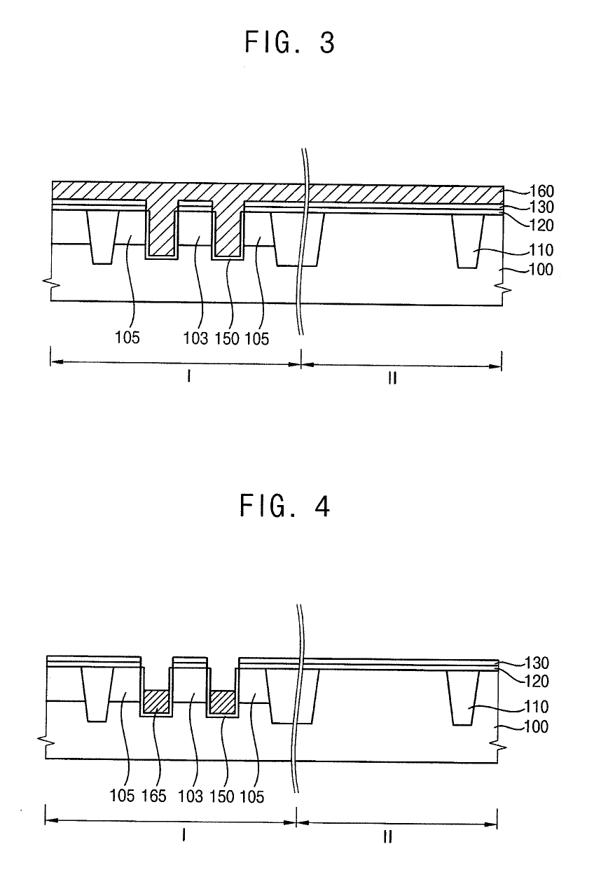

Referring to FIG. 3, a first gate electrode layer 160 may be formed on the first gate insulation layer 150, the mask 120 and the polish stop layer pattern 130 to fill the second trench 140.

For example, the first gate electrode layer 160 may be formed using a metal, a metal nitride and/or a metal silicide such as tungsten or titanium nitride by an atomic layer deposition (ALD) process or a physical vapor deposition (PVD) process. An annealing process such as, for example, a rapid thermal annealing (RTA) process, a spike-RTA process, a flash RTA process, a laser annealing process, etc. may be further performed on the first gate electrode layer 160.

Referring to FIG. 4, an upper portion of the first gate electrode layer 160 may be removed to form a first gate electrode 165 partially filling the second trench 140.

In example embodiments, an upper portion of the first gate electrode layer 160 may be planarized by, for example, a chemical mechanical polishing (CMP) process until a top surface of the polish stop layer pattern 130 is exposed, and a portion of the first gate electrode layer 160 on the second trench 140 may be partially removed by an anisotropic etching process to form the first gate electrode 165.

In example embodiments, the first gate electrode 165 may be formed to have a top surface lower than that of the substrate 100 on which the second trench 140 is not formed.

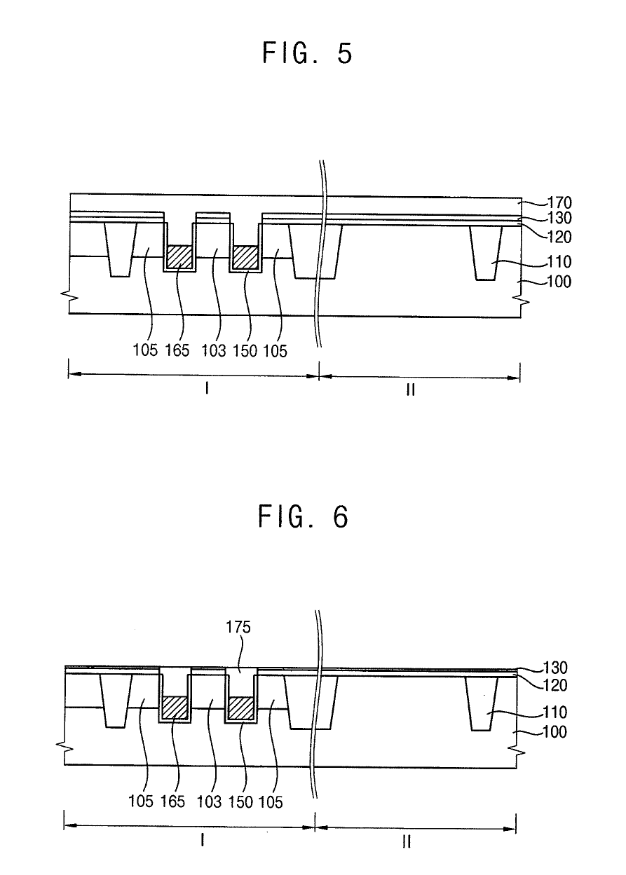

Referring to FIG. 5, a capping layer 170 may be formed on the first gate electrode 165, the first gate insulation layer 150, the mask 120 and the polish stop layer pattern 130 to fill a remaining portion of the second trench 140.

In example embodiments, the capping layer 170 may be formed using silicon oxide. The capping layer 170 may include, for example, an oxide substantially the same as or similar to that of the first gate insulation layer 150, and thus the deterioration of the first gate insulation layer 150 during a process for forming the capping layer 170 and/or a subsequent annealing processes may be prevented.

Referring to FIG. 6, an upper portion of the capping layer 170 may be removed by, for example, a CMP process to form a capping layer pattern 175 filling the remaining portion of the second trench 140. In the CMP process, the polish stop layer pattern 130 may serve as a polishing endpoint, and the polish stop layer pattern 130 may be partially or entirely removed by the CMP process. The first gate electrode 165, the first gate insulation layer 150 and the capping layer pattern 175 may define a first gate structure, namely, the buried gate structure. Additionally, the first gate structure and the first and the second impurity regions 103 and 105 may define a first transistor.

If the capping layer 170 includes a nitride, removing an upper portion of the capping layer 170 by the CMP process may be difficult, and thus an etch back process may be used. In the etch back process, however, the mask 120 may have a thickness thicker than that in the CMP process, and thus the etch back process may not desirable in an aspect of a manufacturing process. On the contrary, in example embodiments, the capping layer 170 may be formed using, for example, silicon oxide, and thus the upper portion of the capping layer 170 may be removed by the CMP process. Accordingly, with example embodiments, the mask 120 may be formed to have a relatively thin thickness.

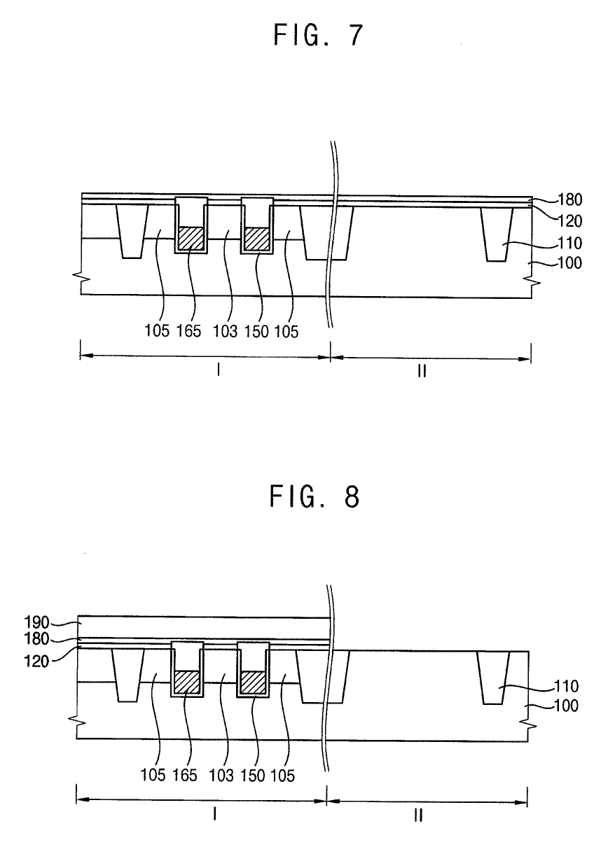

Referring to FIG. 7, a blocking layer 180 may be formed on the capping layer pattern 175 and a remaining portion of the polish stop layer pattern 130.

In example embodiments, the blocking layer 180 may be formed using, for example, a silicon nitride. Accordingly, the remaining portion of the polish stop layer pattern 130 may be merged to the blocking layer 180.

Referring to FIG. 8, a photoresist pattern 190 covering the first region I may be formed on the blocking layer 180, and the blocking layer 180 and the mask 120 may be etched using, for example, the photoresist pattern 190 as etching masks to thereby form a blocking layer pattern 180. Accordingly, the blocking layer pattern 180 and the mask 120 may remain only in the first region I. It is noted that the blocking layer and the blocking layer pattern have been assigned the same reference numeral in the present application.

For example, in example embodiments, a dry etching process may be performed using the photoresist pattern 190 as etching masks. Accordingly, the lifting of the photoresist pattern 190 when a wet etching process is performed using an etching solution may be prevented.

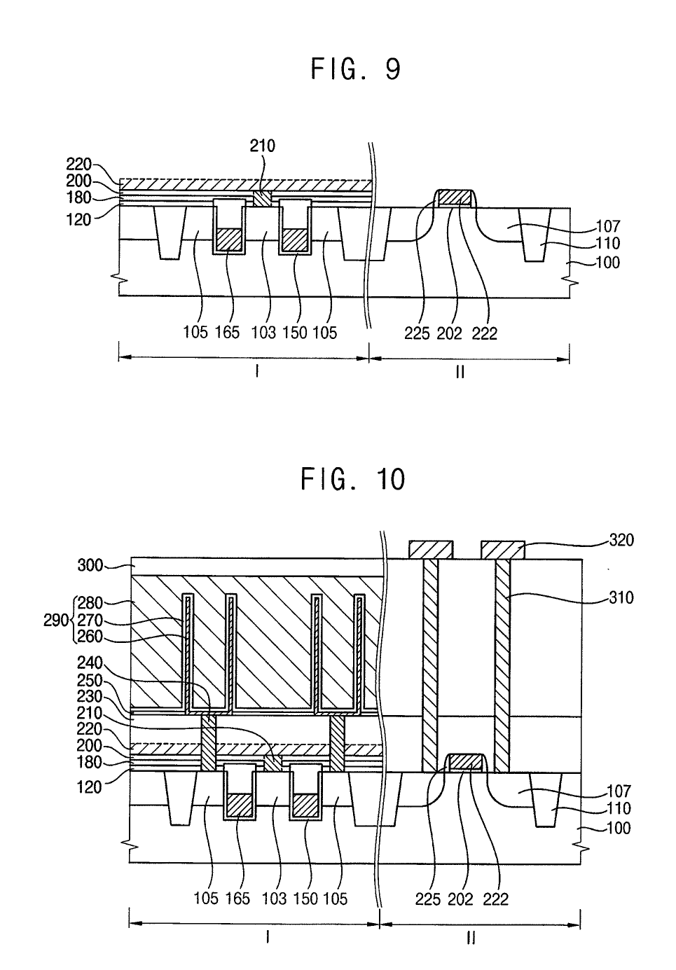

Referring to FIG. 9, after removing the photoresist pattern 190, a second gate insulation layer may be formed on the substrate 100 in the second region II.

In example embodiments, the second gate insulation layer may be formed by, for example, a CVD process using silicon oxide. In the CVD process, a silicon oxide layer 200 may be formed on the blocking layer pattern 180 in the first region I.

A first opening (not shown) may be formed through the second gate insulation layer, the blocking layer pattern 180 and the mask 120, and a first conductive layer may be formed on the substrate 100 and the silicon oxide layer 200 to fill the first opening. An upper portion of the first conductive layer may be planarized to form a first plug 210. In example embodiments, the first conductive layer may be formed using, for example, a metal, a metal nitride, a metal silicide and/or a doped polysilicon.

A second conductive layer may be formed on the silicon oxide layer 200, the first plug 210 and the second gate insulation layer, and may be patterned to form a bit line 220 in the first region I and a second gate electrode 222 in the second region II. The bit line 220 may be electrically connected to the first plug 210.

In example embodiments, the second conductive layer may be patterned by, for example, a plasma etching process. During the plasma etching process, the blocking layer pattern 180 in the first region I may protect a top surface of the substrate 100. Accordingly, the substrate 100 in the first region I in which the memory cells are formed may be protected from the plasma etching damage.

The second gate insulation layer may be patterned using the second gate electrode 222 as an etching mask to form a second gate insulation layer pattern 202. The second gate electrode 222 and the second gate insulation layer pattern 202 may define a second gate structure.

A spacer 225 may be formed on a sidewall of the second gate structure, and a third impurity region 107 may be formed at an upper portion of the substrate 100 adjacent to the second gate structure.

For example, a silicon nitride layer covering the second gate electrode 222 and the second gate insulation layer pattern 202 may be formed on the substrate 100 in the second region II. The silicon nitride layer may be patterned by, for example, an anisotropic etching process to form the spacer 225. The third impurity region 107 may be formed by, for example, an ion implantation process using the second gate structure and the spacer 225 as ion implantation masks.

The second gate structure and the third impurity region 107 may define a second transistor.

Referring to FIG. 10, a first insulating interlayer 230 may be formed on the second gate insulation layer and the substrate 100 to cover the bit line 220, the second gate structure and the spacer 225.

Second openings (not shown) may be formed through the first insulating interlayer 230, the silicon oxide layer 200, the blocking layer pattern 180 and the mask 120 to expose the second impurity regions 105. A third conductive layer may be formed on the second impurity regions 105 and the first insulating interlayer 230 to fill the second openings. The third conductive layer may be formed using, for example, a doped polysilicon, a metal, metal nitride, and/or a metal silicide. An upper portion of the third conductive layer may be planarized until a top surface of the first insulating interlayer 230 is exposed to form second plugs 240 in the second openings that may be electrically connected to the second impurity regions 105

A polish stop layer 250 and a mold layer (not shown) may be sequentially formed on the second plugs 240 and the first insulating interlayer 230. In example embodiments, the polish stop layer 250 may be formed using, for example, silicon nitride and the mold layer may be formed using silicon oxide. Third openings (not shown) may be formed through the mold layer and the polish stop layer 250 to expose the second plugs 240. A fourth conductive layer may be formed on bottoms and sidewalls of the third openings and on the mold layer. A sacrificial layer (not shown) may be formed on the fourth conductive layer to fill remaining portions of the third openings. The fourth conductive layer may be formed using, for example, a doped polysilicon, a metal, metal nitride and/or metal silicide. The sacrificial layer and an upper portion of the fourth conductive layer may be planarized until a top surface of the mold layer is exposed, and the sacrificial layer may be removed. Accordingly, a lower electrode 260 may be formed on the bottoms and the sidewalls of the third openings.

A dielectric layer 270 may be formed on the lower electrode 260 and the polish stop layer 250. The dielectric layer 270 may be formed using, for example, a material having a higher dielectric constant than that of silicon nitride or silicon oxide, e.g., hafnium oxide, titanium oxide, tantalum oxide, zirconium oxide, aluminum oxide, etc.

An upper electrode 280 may be formed on the dielectric layer 270. The upper electrode 280 may be formed using, for example, a doped polysilicon, a metal, metal nitride and/or metal silicide.

The lower electrode 260, the dielectric layer 270 and the upper electrode 280 may define a capacitor 290.

A second insulating interlayer 300 may be formed on the first insulating interlayer 230 to cover the capacitor 290. Fourth openings (not shown) may be formed through the first and second insulating interlayers 230 and 300 in the second region II to expose the third impurity region 107. A fifth conductive layer may be formed on the third impurity region 107 and the second insulating interlayer 300 to fill the fourth openings. An upper portion of the fifth conductive layer may be planarized until a top surface of the second insulating interlayer 300 is exposed to form a third plug 310 electrically connected to the third impurity region 107.

A wiring 320 electrically connected to the third plug 310 may be formed on the second insulating interlayer 300, and a protection layer (not shown) protecting the wiring 320 may be formed to complete the semiconductor device.

In the method of manufacturing the semiconductor device, the capping layer pattern 175 including an oxide may be formed on the buried first gate electrode 165, and thus the first gate insulation layer 150 including an oxide may not have a stress during a process for forming the capping layer pattern 175 and processes thereafter. Accordingly, the first gate insulation layer 150 may have good characteristics. Additionally, the blocking layer pattern 180 including a nitride may be formed on the substrate 100 in the first region I, and thus the substrate 100 may be protected from a plasma damage during a subsequent process for forming the bit line 220. To form the blocking layer pattern 180, the blocking layer 180 in the second region II may be removed by, for example, a dry etching process using the photoresist pattern 190, thereby to prevent the lifting of the photoresist pattern 190.

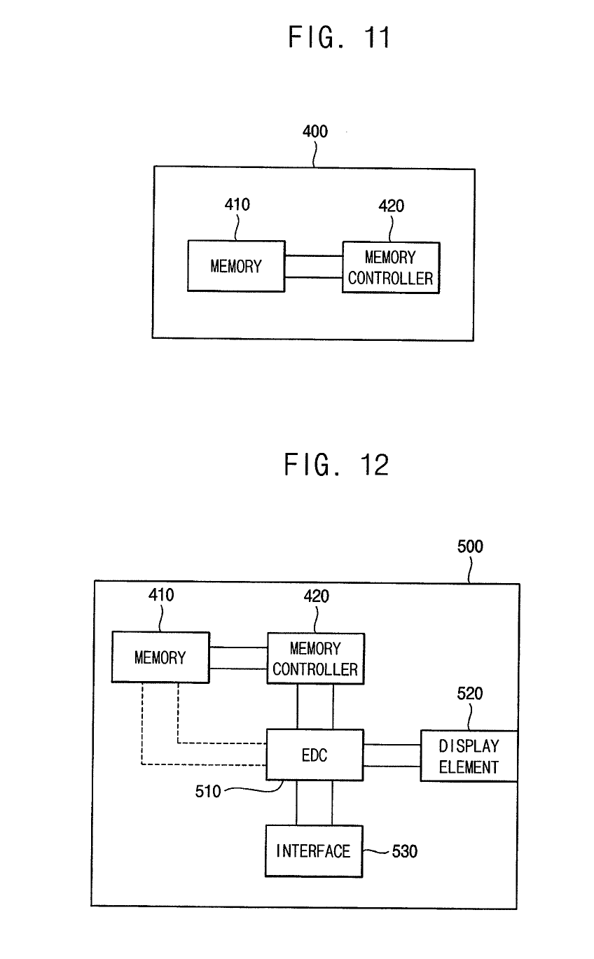

FIG. 11 is a block diagram illustrating a memory card having the buried gate structure in accordance with example embodiments.

Referring to FIG. 11, a memory card 400 may include, for example, a memory 410 and a memory controller 420 electrically connected to each other. The memory 410 may be, for example, a DRAM device having the buried gate structure in accordance with example embodiments.

The memory controller 420 may provide the memory 410 with input signals for controlling the operation of the memory 410.

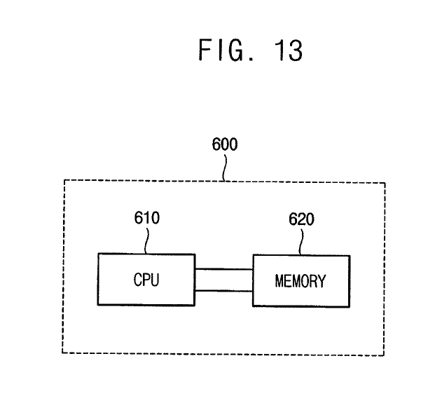

FIG. 12 is a block diagram illustrating a portable device having the buried gate structure in accordance with example embodiments.

A portable device 500 may include, for example, an MP3 player, a video player, or a portable multi-media player (PMP). As shown in FIG. 12, the portable device 500 may include, for example, a memory 410 having the buried gate structure in accordance with example embodiments, and a memory controller 420. The portable device 500 may also include, for example, an encoder/decoder (EDC) 510, a display member 520, and an interface 530.

The EDC 510 may input and/or output data from the memory 410 through the memory controller 420. As shown by a dotted line of FIG. 12, the data may be input from the EDC 510 to the memory 410 directly or output from the memory 410 to the EDC 510 directly.

The EDC 510 may encode data to be stored in the memory 410. For example, the EDC 510 may execute encoding for storing audio data and/or video data in the memory 410 of an MP3 player or a PMP player. Furthermore, the EDC 510 may execute MPEG encoding for storing video data in the memory 410. The EDC 510 may include multiple encoders to encode different types of data depending on their formats. For example, the EDC 510 may include an MP3 encoder for encoding audio data and an MPEG encoder for encoding video data.

The EDC 510 may also decode data being output from the memory 610. For example, the EDC 510 may decode MP3 audio data from the memory 410. Furthermore, the EDC 510 may decode MPEG video data from the memory 410. The EDC 510 may include multiple decoders to decode different types of data depending on their formats. For example, the EDC 510 may include an MP3 decoder for audio data and an MPEG decoder for video data.

The EDC 510 may include only a decoder. For example, encoded data may be input to the EDC 510, and then the EDC 510 may decode the input data and transfer the decoded data to the memory controller 420 or the memory 410.

The EDC 510 may receive data to be encoded or data being encoded by way of the interface 530. The interface 530 may be compliant with standard input devices, e.g. FireWire, or an USB. That is, the interface 530 may include, for example, a FireWire interface, an USB interface or the like. Data is output from the memory 410 by way of the interface 530.

The display element 520 may display to an end user data output from the memory 410 and decoded by the EDC 510. For example, the display element 520 may be an audio speaker or a display screen.

FIG. 13 is a block diagram illustrating a computer system having the buried gate structure in accordance with example embodiments.

Referring to FIG. 13, the computer system 600 may include, for example, a memory 620 and a central processing unit (CPU) 610 connected to each other. For example, the computer system 600 may be a personnel computer or a personnel computer assistant. The memory may be connected to the CPU directly or through a BUS.

Having described the exemplary embodiments of the present invention, it is further noted that it is readily apparent to those of reasonable skill in the art that various modifications may be made without departing from the spirit and scope of the invention which is defined by the metes and bounds of the appended claims.

1. A gate structure comprising:
a gate insulation layer formed on an inner wall of a recess in a substrate;
a gate electrode formed on the gate insulation layer, the gate electrode partially filling the recess; and
a capping layer pattern formed on the gate electrode and the gate insulation layer, the capping layer pattern filling a remaining portion of the recess and including silicon oxide.

2. The gate structure of claim 1, wherein the gate insulation layer includes silicon oxide.

3. The gate structure of claim 1, wherein the capping layer pattern protrudes from a top surface of the substrate.

4. A semiconductor device comprising:
a first transistor including:
a first gate structure including:
a first gate insulation layer formed on an inner wall of a recess in a substrate in a first region, the substrate being divided into the first region and a second region,
a first gate electrode formed on the first gate insulation layer, the first gate electrode partially filling the recess, and
a capping layer pattern formed on the first gate electrode and the first gate insulation layer, the capping layer pattern filling a remaining portion of the recess and including silicon oxide; and
a first impurity region and a second impurity region formed at upper portions of the substrate in the first region adjacent to the first gate structure;
a blocking layer pattern formed on the substrate in the first region, the blocking layer pattern covering the first transistor;
a bit line formed on the blocking layer pattern, the bit line being electrically connected to the first impurity region;
a capacitor electrically connected to the second impurity region; and
a second transistor formed on the substrate in the second region.

5. The semiconductor device of claim 4, wherein the first gate insulation layer includes silicon oxide.

6. The semiconductor device of claim 4, wherein the blocking layer pattern includes silicon nitride.

7. The semiconductor device of claim 4, wherein the capping layer pattern protrudes from a top surface of the substrate.

8. The semiconductor device of claim 4, further comprising a silicon oxide layer formed on the blocking layer pattern.

9. The semiconductor device of claim 8, wherein the second transistor includes:
a second gate structure including a second gate insulation layer pattern and a second gate electrode sequentially stacked on the substrate in the second region; and
a third impurity region at an upper portion of a substrate adjacent to the second gate structure in a second region, and
wherein the second gate insulation layer pattern includes a material substantially the same as a material of the silicon oxide layer.

10. The semiconductor device of claim 8, further comprising a plug through the blocking layer pattern and the mask, the plug contacting the bit line and the first impurity region.

11-20. (canceled)
